(19) United States
(12) Patent Application Publication
(10) Pub. No.: US 2019/0371668 A1
(43) Pub. Date: Dec. 5, 2019

(54) ELEMENT CHIP MANUFACTURING METHOD

(71) Applicant: Panasonic Intellectual Property Management Co., Ltd., Osaka (JP)

(72) Inventors: Hidehiko KARASAKI, Hyogo (JP); Shogo OKITA, Hyogo (JP); Noriyuki MATSUBARA, Yamanashi (JP); Atsushi HARIKAI, Osaka (JP)

(21) Appl. No.: 16/426,076

(22) Filed: May 30, 2019

(30) Foreign Application Priority Data
Jun. 5, 2018 (JP) 2018-107942

(51) Int. Cl. H01L 21/78; H01L 23/544; H01L 21/268; H01L 21/3065; H01L 21/683; B23K 26/364

(52) U.S. Cl. CPC H01L 21/78; H01L 23/544; H01L 21/268; H01L 21/3065; H01L 2221/68381; B23K 26/364; H01L 2223/5446; H01L 2221/6834; H01L 2221/68327; H01L 21/6836

(57) ABSTRACT

A substrate has first and second surfaces, and includes a plurality of element regions and dividing region defining the element regions. An method for manufacturing an element chip includes: a protective film formation step of applying a mixture containing a water-soluble resin and a solvent to the first surface, to form a protective film; a laser grooving step of irradiating, with laser light, portions of the protective film covering the dividing regions, to remove these portions, and expose the first surface in the dividing regions; a step of dicing the substrate into element chips by plasma etching the substrate in the dividing regions; and a step of removing the portions of the protective film. The resin has melting point of 250° C. or more, or decomposition temperature of 450° C. or more, and the protective film has absorption coefficient of 1 abs·L/g·cm⁻¹ or more for wavelength of the laser light.

### CROSS REFERENCE TO RELATED APPLICATION

The present application is based on and claims priority under 35 U.S.C. § 119 with respect to the Japanese Patent Application No. 2018-107942 filed on Jun. 5, 2018, of which entire content is incorporated herein by reference into the present application.

### TECHNICAL FIELD

The present disclosure relates to a method for manufacturing an element chip that uses plasma etching.

### BACKGROUND

Conventionally, when dicing a semiconductor substrate into a plurality of element chips, processing grooves are formed in advance along portions to be diced (also referred to as “streets” or “dividing regions”) by a grooving step (laser grooving step) using laser light, prior to dicing. Then, dicing is performed by cutting the substrate along the processing grooves using a cutting blade or laser light. To prevent processing debris generated by laser light from attaching to the substrate in the laser grooving step, a mask (protective film) is formed to protect the element regions, prior to the laser grooving step. As the mask, a coating film of a water-soluble resin may be used. The use of a coating film of a water-soluble resin as the mask is convenient because the mask can be removed using water. As described in Japanese Laid-Open Patent Publication No. 2006-140311, polyvinyl alcohol, which is readily available and inexpensive, is often used as the water-soluble resin.

Meanwhile, in recent years, a technique that uses dicing for plasma etching has been proposed (Japanese Laid-Open Patent Publication No. 2008-53417). The use of plasma etching enables a semiconductor substrate to be divided into many element chips at one time, and is therefore advantageous in terms of cost. In dicing that uses plasma etching (plasma dicing) as well, prior to the plasma etching, laser grooving is performed in which the portions of the protective film that cover the dividing regions are removed using laser light (Japanese Laid-Open Patent Publication No. 2008-53417).

### SUMMARY

An aspect of the present disclosure relates to a method for manufacturing an element chip,

the method including:

a preparation step of preparing a substrate, the substrate having a first surface and a second surface opposite to the first surface, and including a plurality of element regions and dividing regions defining the element regions, the substrate being held on a holding sheet on the second surface side;

a protective film formation step of applying a mixture containing a water-soluble resin and a solvent to the first surface of the substrate, to form a protective film containing the water-soluble resin;

a laser grooving step of irradiating, with laser light, portions of the protective film that cover the dividing regions, to remove the portions covering the dividing regions, and expose the first surface of the substrate in the dividing regions;

a dicing step of dicing the substrate into a plurality of element chips by plasma etching the substrate from the first surface to the second surface in the dividing regions in a state in which the element regions are covered by the protective film; and

a removal step of removing the portions of the protective film that cover the element regions,

wherein the water-soluble resin has a melting point of 250° C. or more, or a decomposition temperature of 450° C. or more, and

the protective film has an absorption coefficient of 1 abs·L/g·cm⁻¹ or more for a wavelength of the laser light.

### BRIEF DESCRIPTION OF THE DRAWINGS

FIG. 1 is a flowchart showing a method for manufacturing an element chip according to an embodiment of the present disclosure.

FIG. 2 is a schematic diagram for illustrating a substrate.

FIG. 3 is a schematic diagram for illustrating a substrate fixed to a transport carrier.

FIG. 4 is a schematic cross-sectional view for illustrating a coating film formed by applying a mixture containing a water-soluble resin and a solvent in a protective film formation step of the method according to the present embodiment.

FIG. 5 is a schematic cross-sectional view for illustrating a laser grooving step.

FIG. 6 is a schematic cross-sectional view for illustrating element chips that have been diced by a dicing step.

FIG. 7 is a schematic cross-sectional view for illustrating the element chips in a state in which the protective film has been removed.

FIG. 8 is a schematic diagram showing an example of a dry etching apparatus.

FIG. 9 shows a measurement result of 3D mapping using a laser microscope, showing the state of the protective film after laser grooving in Example 1.

FIG. 10 shows a measurement result of 3D mapping, showing the state of the protective film after laser grooving in Comparative Example 1.

FIG. 11 is a scanning electron microscope (SEM) photograph showing the state of the protective film of Example 1 after dicing.

FIG. 12 is a SEM photograph showing the state of the protective film after dicing in Comparative Example 1.

FIG. 13 is a photograph, observed with a laser microscope, of the state of element chips after removing the protective film in Example 1, as viewed from above.

FIG. 14 is a photograph, observed with a laser microscope, of the state of element chips after removing the protective film in Comparative Example 1, as viewed from above.

### DETAILED DESCRIPTION

A novel feature of the present invention is set forth in the appended claims, but the present invention will be more clearly understood, in terms of both configuration and content, from the detailed description given below with reference to the accompanying drawings together with other objects and features of the present invention.

Unlike the conventional dicing using a cutting blade or the like, plasma etching causes the semiconductor substrate to be exposed to a relatively high temperature, and also causes the entire protective film to be exposed to a high temperature and plasma. Accordingly, during plasma dicing, the protective film may deteriorate, or the protective film may partially undergo peeling (also referred to as “delamination”) from the semiconductor substrate. Depending on the material and the thickness of the protective film, it may not be possible to cleanly remove the protective film from the dividing regions during laser grooving. When peeling of the protective film occurs, or the protective film remains in the dividing regions, during plasma etching in the dicing step, the plasma may enter into the portions where the protective film has been peeled, and etching does not proceed uniformly, so that dicing may not be performed successfully, or the end faces of the element chips may be distorted. Furthermore, if there is any portion in the dividing regions where the protective film remains, that portions will not be etched, thus resulting in dicing failure.

According to the present disclosure, it is possible to perform more uniform dicing processing in dicing that uses plasma etching.

An embodiment of the method for manufacturing an element chip according to the present disclosure will be described with reference to the accompanying drawings. In the description of the embodiment, terms (e.g., “upper”) that are used to indicate directions in order to facilitate the understanding are merely illustrative, and these terms are not intended to limit the method according to the present disclosure. In the drawings, constituent parts are illustrated in relative dimensions in order to clarify the shape and the characteristics thereof, and are not necessarily shown with the same scale ratio.

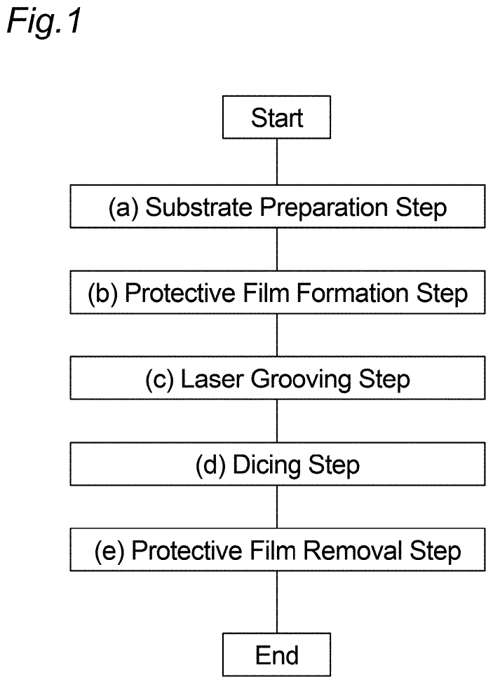

As schematically shown in the flowchart in FIG. 1, a method for manufacturing an element chip according to an aspect of the present disclosure includes the steps of: (a) preparing a substrate that includes a plurality of element regions, and dividing regions defining the element regions, and that is held by a holding sheet (substrate preparation step); (b) forming a protective film containing a water-soluble resin by using a mixture containing the water-soluble resin and a solvent (protective film formation step); (c) removing portions of the protective film that cover the dividing regions by irradiation with laser light (laser grooving step); (d) dicing the substrate into a plurality of element chips in the dividing regions by plasma etching the substrate from a front surface to a back surface (dicing step); and (e) removing the protective film (protective film removal step). Here, the water-soluble resin has a melting point of 250° C. or more, or a decomposition temperature of 450° C. or more, and the protective film has an absorption coefficient of 1 abs·L/g·cm⁻¹ or more for the wavelength of the laser light irradiated in the laser grooving step.

When dicing the substrate, a protective film is formed on the surface of the substrate. In the conventional dicing in which a cutting blade is used after processing grooves using laser light (laser grooving), it is sufficient that debris generated during the laser grooving can be prevented from attaching to the substrate. Therefore, the protective film has a small thickness, usually, a thickness less than 1 μm. However, it has been found that when the substrate on which such a protective film is formed is diced by plasma etching, the plasma etching cannot be performed uniformly.

Irregularities due to pad electrodes, bumps, and the like may be provided on the surface of a commonly used element. If the thickness of the protective film is less than 1 μm, areas in which the protective film is thinly coated may be produced, depending on the surface structure of the element regions, or the coverage of the surface irregularities by a protective film forming material. If the areas where the protective film is thinly coated exist, the protective film may be eliminated in the thinly coated areas during plasma etching, so that the surfaces of the element regions may be exposed to plasma, resulting in pinhole-like processing marks. Furthermore, if the electrode section is exposed at the portions where the protective film has been eliminated, an electrical damage may be caused to the elements, or the inner wall of a plasma etching device may be contaminated with the metals from the electrode section.

When the substrate is subjected to a plasma treatment, a cured layer or a modified layer may be formed on the surface of the water-soluble protective film, or the polymerization of the materials constituting the protective film may progress. As a result, the solubility of the water-soluble protective film is reduced. If the thickness of the protective film is less than 1 μm, the cured layer, the modified layer, or the polymerized layer tend to extend not only over the surface layer, but also over the entire depth direction of the substrate. In this case, even if the protective film remaining after plasma etching is subjected to water washing or the like, it will be difficult to remove the protective film cleanly.

After performing dicing by plasma etching, it is possible to expose the cured layer, the modified layer, or the polymerized layer to a plasma of oxygen, to remove these layers, and then remove the protective film by water washing. However, if the thickness of the protective film is less than 1 μm, the protective film may be partially or entirely removed during the oxygen plasma treatment. This is not preferable because the surfaces of the element regions are exposed to the plasma in the portions where the protective film has been removed, and the elements are thus damaged. Therefore, when performing plasma etching, it is necessary to form a protective film having a large thickness.

In Japanese Laid-Open Patent Publication No. 2008-53417, the protective film is formed using polyvinyl alcohol (PVA). Since PVA tends to increase the viscosity of a coating solution, the thickness of the protective film must be reduced when a certain degree of applicability is ensured. In the case of forming a protective film having a large thickness using PVA, application of the coating solution needs to be repeated many times, resulting in a significant increase in the time required to form the protective film. When a protective film having a large thickness that has been formed using PVA is subjected to laser grooving, the PVA is heated and melted around the portions removed with laser, and may flow into the portions removed with laser. In this case, the portions of the protective film that cover the dividing regions cannot be removed cleanly, so that the protective film may partially remain on the dividing regions, or the shape of the side surfaces of the processing grooves may be distorted. In addition, the PVA may be softened around the processing grooves, so that the inclination of the side surfaces of the processing grooves may be reduced. If the substrate in such a state is subjected to the dicing step using plasma etching, only the portions where the protective film has been removed can be etched, or the dividing region width may need to be set to be large in advance, taking into consideration the inclination of the side surfaces of the processing grooves. If the dividing region width is set to be large, the number of element regions disposed on the substrate, i.e., the number of elements produced per substrate, is decreased. In the case of PVA, when the protective film has a large thickness, the difference in the coefficient of thermal expansion due to exposure to plasma between the protective film and the substrate is increased, and partial peeling of the protective film tends to occur. Accordingly, the dividing regions cannot be etched cleanly. As a result, dicing may not be performed successfully, or the element chips may have a distorted shape or a distorted end face. In order for a protective film using PVA to be subjected to plasma etching, it is necessary, after applying a coating solution for forming the protective film onto the substrate, to bake the coating film once so as to increase the resistance to plasma and heat. Accordingly, the element chip manufacturing additionally requires the baking time and a cooling time to bring the temperature to room temperature, resulting in a significant reduction in the productivity.

In contrast, according to the above-described aspect of the present disclosure, a water-soluble resin having a melting point of 250° C. or more, or a decomposition temperature of 450° C. or more is used for the protective film, and the protective film has an absorption coefficient of 1 abs·L/g·cm⁻¹ or more for the wavelength of the laser light irradiated in the laser grooving step. In the laser grooving step, the laser light absorption of the protective film is increased, so that the protective film having a large thickness for plasma dicing can be easily abraded with a small amount of energy, resulting in an increase in the removability of the protective film. In addition, even when the protective film has a large thickness, the protective film can be abraded with a small amount of energy, and it is therefore possible to suppress melting or softening of the protective film around the portions removed with laser. Accordingly, even when the protective film has a large thickness, the portions of the protective film that cover the dividing regions can be cleanly removed. As a result, in the laser grooving step, it is possible to form processing grooves having a high aspect ratio, wherein the inclination of the side surfaces of the processing grooves is steep (forward-tapered or vertical), and the opening width thereof is narrow and substantially equal to the laser irradiation width. Furthermore, the protective film has a higher heat resistance, and the peeling of the protective film from the substrate can be effectively suppressed even when the protective film is subjected to plasma etching. Accordingly, plasma etching can be more uniformly performed using, as a mask, a neatly shaped protective film formed on the substrate, making it possible to obtain neatly shaped element chips. Thus, it is possible to perform more uniform dicing processing.

In the following, each of the steps will be described more specifically.

### (a) Substrate Preparation Step

A substrate that is prepared in a substrate preparation step is diced into a plurality of element chips by using a plasma etching technique. The substrate may be a semiconductor substrate such as a silicon wafer, a resin substrate such as a flexible printed substrate, a ceramic substrate, or the like, and the semiconductor substrate may be formed of silicon (Si), gallium arsenide (GaAs), gallium nitride (GaN), silicon carbide (SiC), or the like. The present disclosure is not limited to the materials and the like of the substrate.

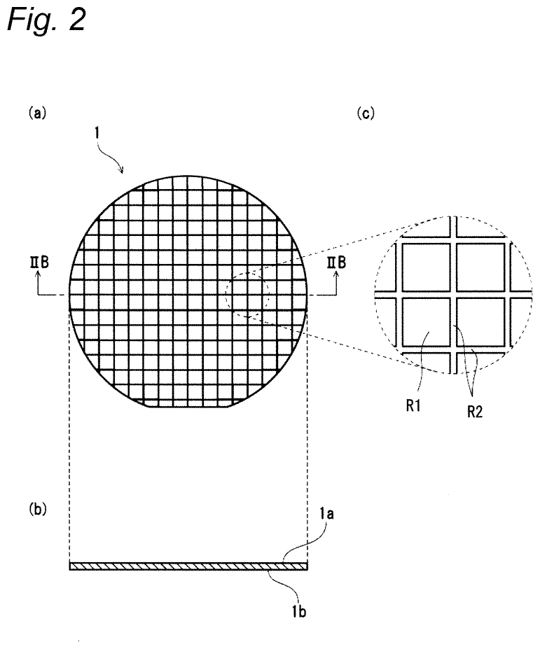

FIG. 2 is a schematic diagram for illustrating a substrate 1. (a) of FIG. 2 is a plan view of the substrate 1 as viewed from above, (b) of FIG. 2 is a cross-sectional view taken along the line IIB-IIB in (a) of FIG. 2, and (c) of FIG. 2 is a partial enlarged view of (a) of FIG. 2. As shown in (b) of FIG. 2, the substrate 1 includes a first surface 1a and a second surface 1b (hereinafter also referred to as “front surface 1a” and “back surface 1b”) that oppose each other. As shown in (c) of FIG. 2, the substrate 1 includes, on the front surface 1a thereof, a plurality of element regions R1, and dividing region R2 defining the element regions R1. Each of the element regions R1 of the substrate 1 includes an integrated circuit constituting a desired electric circuit, and will constitute an element chip after a plasma etching step. The dividing regions R2 constitute dicing lines.

Usually, an electric integrated circuit is formed in each element region R1, and an exposed circuit, a bump, and the like are present. The electric circuit on the front surface 1a of each of the element regions R1 may include a circuit layer of a semiconductor circuit, an electronic component element, a MEMS, or the like. However, the circuit layer is not limited thereto. The circuit layer may be configured as a multilayer stack including an insulating film, a conductive layer, a resin protective layer, an electrode pad, a terminal section, and so forth. The bump is connected to the terminal section of the multilayer stack.

After the multilayer stack is formed, the back surface 1b of the substrate 1 may be polished in order to reduce the thickness of the substrate 1. More specifically, the front surface 1a including the circuit layer may be protected by being covered with backgrind (BG) tape, and the back surface 1b of the substrate 1 may be polished.

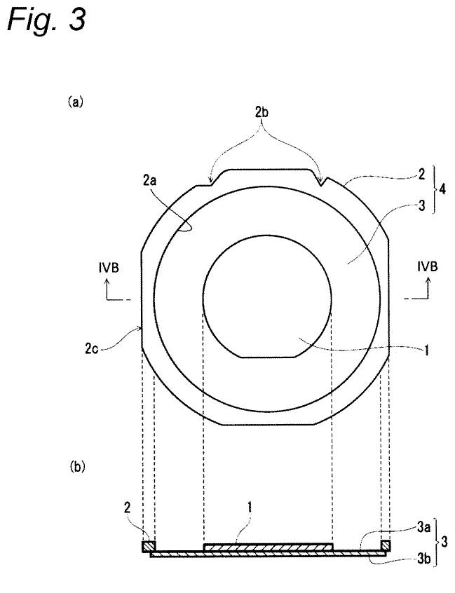

The substrate 1 has any planar shape, for example, a substantially circular planar shape as shown in (a) of FIG. 3. Besides a circular shape, the planar shape of the substrate 1 may be rectangular, and may have an orientation flat ((a) of FIG. 3), and a cutout such as a notch. The maximum diameter of the substrate 1 is not particularly limited, and is, for example, 50 mm or more and 300 mm or less, and the thickness thereof is not particularly limited, and is, for example, 10 μm or more and 800 μm or less.

The substrate 1 and a frame 2 are held by a holding sheet 3 when a desired electric integrated circuit is formed in each element region R1, or at least before a protective film formation step described below. The frame 2 may be held by the holding sheet 3 in advance. Alternatively, the frame 2 may be held by the holding sheet 3 after the substrate 1 has been held by the holding sheet 3. (a) of FIG. 3 is a plan view of the substrate 1 and the frame 2 that are fixed to the holding sheet 3, as viewed from above, and (b) of FIG. 3 is a cross-sectional view taken along the line IVB-IVB in (a) of FIG. 3. The holding sheet 3 has an upper surface (adhesive surface 3a) that contains an adhesive agent, and a lower surface (non-adhesive surface 3b) that does not contain an adhesive agent. As a result of the substrate 1 and the frame 2 being fixed to the adhesive surface 3a, the holding sheet 3 holds the substrate 1 and the frame 2 from the back surface 1b side of the substrate 1. The frame 2 has an annular shape including a circular opening 2a. The frame 2 is held by the holding sheet 3 such that the opening 2a and the substrate 1 are disposed concentrically, and the adhesive surface 3a is exposed in the opening 2a that is not covered by the substrate 1. In the present specification, a combination of the holding sheet 3 and the frame 2 fixed thereto is referred to as a “transport carrier 4”, and the substrate 1 that is fixed to the transport carrier 4 is also referred to as a “carrier-equipped substrate 1”. Even though the substrate 1 itself is thin, the substrate 1 is held by the transport carrier 4, and therefore can be easily operated and transported in a subsequent step.

The base material of the holding sheet 3 is formed using a thermoplastic resin such as polyolefins, including, for example, polyethylene and polypropylene, and polyesters including, for example, polyethylene terephthalate. The holding sheet 3 may have stretchability so as to be removed from the frame 2 after a protective film removal step described below, and be expanded in the radial direction to widen the intervals between the individual element chips, thus allowing the element chips to be easily picked up from the adhesive surface 3a. The base material of the holding sheet 3 may contain various additives such as a rubber component for providing stretchability (e.g., an ethylene-propylene rubber (EPM), an ethylene-propylene-diene rubber (EPDM)), a plasticizer, a softening agent, an antioxidant, and a conductive material. The thermoplastic resin may include a functional group exhibiting photopolymerization reaction, such as an acrylic group. The thickness of the base material of the holding sheet 3 is not particularly limited, and is, for example, 50 μm or more and 150 μm or less.

On the other hand, the adhesive surface 3a of the holding sheet 3 is preferably made of an adhesive component whose adhesive force can be reduced. This is to allow the diced element chips to be more easily picked up from the adhesive surface 3a by irradiation with ultraviolet light (UV light) after a dicing step described below. The holding sheet 3 may be formed, for example, by applying, onto one surface of a film-like base material, a UV-curable acrylic adhesive agent in a thickness of 5 μm or more and 20 μm or less.

The frame 2 has a rigidity sufficient to be able to transport the substrate 1 and the holding sheet 3 in a state in which the substrate 1 and the holding sheet 3 are held thereby. The opening 2a of the frame 2 may have a polygonal shape such as a rectangular shape or a hexagonal shape, in addition to the above-described circular shape. As shown in FIG. 3, the frame 2 may include notches 2b or corner cuts 2c for positioning. The frame 2 may be formed using, for example, a metal such as aluminum and stainless steel, or a resin.

### (b) Protective Film Formation Step

In a protective film formation step, a protective film containing a water-soluble resin is formed by applying a mixture containing the water-soluble resin and a solvent onto the front surface 1a of the substrate 1. Usually, the protective film is formed by drying a coating film of the mixture.

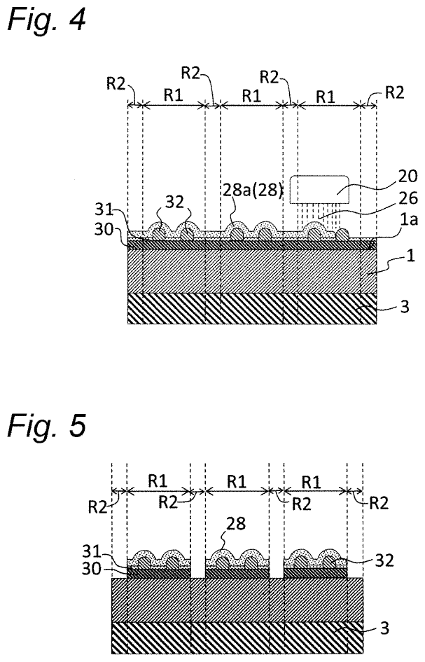

FIG. 4 is a schematic cross-sectional view for illustrating a coating film formed by applying a mixture containing a water-soluble resin and a solvent in the protective film formation step of the method according to the present embodiment. FIG. 4 shows an example in which a circuit layer including projection-shaped bumps 32 is formed in each of the plurality of element regions R1 on the front surface 1a of the substrate 1. Although the structure of the circuit layer is not particularly limited, here, a case is described where the circuit layer includes a multilayer wiring layer 30, an insulating protective layer 31 that protects the multilayer wiring layer 30, and projection-shaped bumps 32 connected to a terminal section of the multilayer wiring layer 30. The arrangement of the multilayer wiring layer 30 is not particularly limited, and the multilayer wiring layer 30 may be disposed in both the element regions R1 and the dividing regions R2 as shown in FIG. 4, or may be disposed only in the element regions R1.

Although FIG. 4 shows an example in which a spray coating device is used to spray coat a mixture 26 from a nozzle 20 of the spray coating device, the application method is not limited to this example, and it is possible to use, for example, a different method such as spin coating. Alternatively, spray coating and spin coating may be performed in combination.

For spray coating, it is possible to use, for example, various spray coating devices such as an inkjet, ultrasonic, two-fluid mixing, and electrostatic spray coating devices. In spin coating, with the use of a spin coating device, the mixture 26 can be applied onto the entire front surface 1a of the substrate 1, for example, by dropping the mixture 26 from the vicinity of the center of the substrate 1, while rotating the substrate 1 about the rotational shaft in the vertical direction.

The application of the mixture 26 may be performed at least once, but may be repeated a plurality of times. By repeating the application a plurality of times, the thickness of the protective film 28 can be increased. In the case of repeating the application of the mixture 26 a plurality of times, it is common to use a method in which a coating film 28a formed is dried each time the application is performed once. In the case of performing, for example, spray coating and spin coating in combination, spin coating (and optionally drying) may be performed after repeating spray coating (and optionally drying) a plurality of times. If necessary, spin coating (and optionally drying) may be further repeated. In the case of performing the application a plurality of times, mixtures 26 having different compositions (components, concentrations and/or viscosities, etc.) may be used at respectively different times of application, or mixtures 26 having the same composition may be used at least some of the plurality of times of application.

As the water-soluble resin, a water-soluble resin having a melting point of 250° C. or more, or a decomposition temperature of 450° C. or more can be used. By using a water-soluble resin having such properties, the protective film 28 located around the portions removed by laser can be prevented from being excessively heated and softened or melted to flow into the processing grooves formed with laser in the laser grooving step. Accordingly, the portions of the protective film 28 that cover the dividing regions R2 can be removed cleanly. In addition, it is possible to form processing grooves having a high aspect ratio, wherein the inclination of the side surfaces of the processing grooves is steep (forward-tapered or vertical), and the opening width thereof is narrow and substantially equal to the laser irradiation width. Furthermore, since the protective film 28 has high heat resistance, it is possible to prevent the peeling of the protective film 28 in the dicing step. The melting point of the water-soluble resin may be 250° C. or more, and may be 270° C. or more, or 300° C. or more. The upper limit of the melting point of the water-soluble resin is not particularly limited. The decomposition temperature of the water-soluble resin may be 450° C. or more, and may be 600° C. or more. The upper limit of the decomposition temperature of the water-soluble resin is not particularly limited. In general, the melting point and the decomposition temperature of an organic compound increase when the molecular weight of the organic compound increases. However, with the method according to the present disclosure, it is possible to ensure high laser processability by using a water-soluble resin having at least one of a melting point and a decomposition temperature that satisfy the above-described ranges.

Preferably, the water-soluble resin is capable of absorbing the laser light irradiated in the laser grooving step. The water-soluble resin as mentioned herein does not include a solvent, which is volatilized during drying, and the absorbing capability refers to that of the main material (e.g., including the mixture in which an UV absorber is mixed, excluding a solvent). If the water-soluble resin is capable of absorbing the laser light, the abrasion properties can be increased with a small amount of energy since the resin itself receives the laser light even when the protective film 28 has a large thickness. In addition, the absorption coefficient of the protective film 28 can be more easily regulated. If the water-soluble resin has low laser light absorption, it is preferable to use a photosensitizer as will be described below, from the viewpoint of increasing the absorption coefficient of the protective film 28 to ensure high abrasion properties.

Examples of the water-soluble resin include a water-soluble polyester, polystyrene sulfonic acid, polyacrylic acid, polymethacrylic acid, polyacrylamide, 2-acrylamide-2-methylpropane sulfonic acid, an oxazol-based water-soluble polymer (e.g., oxazol-2-ethyl-4,5-dihydro-homopolymer), or salts (e.g., alkali metal salt, ammonium salt) thereof. Examples of the alkali metal salt include a lithium salt, a sodium salt, and a potassium salt. The melting point of the water-soluble resin can be adjusted by adjusting the degree of polymerization or the molecular weight. The water-soluble resin may be used alone or in combination of two or more. In view of the fact that an excessive deterioration of the protective film 28 is less likely to occur in the dicing step, and the effect of suppressing the peeling of the protective film 28 is high, it is preferable to use a water-soluble polyester, polystyrene sulfonic acid, an oxazol-based water-soluble polymer, or salts thereof. Note that the laser light absorption of the water-soluble resin may also be regulated by introducing, into the water-soluble resin, a functional group (e.g., an aromatic ring, a carbonyl group, a nitrogen-containing group, a sulfur-containing group) having an absorption in the wavelength range of the laser light, or by regulating the amount of the functional group introduced.

Examples of the solvent contained in the mixture 26 include water and an organic solvent. The solvent may be used alone or in a combination of two or more. For example, it is possible to use water and an organic solvent in combination. As the organic solvent, it is preferable to use a water-soluble organic solvent, for example. The organic solvent is preferably an organic solvent having a low absorbance at the wavelength of the laser light irradiated in the laser grooving step, more preferably an organic solvent that does not absorb laser light. Examples of the organic solvent include alcohol, ether, ketone, nitrile, and amide. Examples of the water-soluble organic solvent include methanol, ethanol, acetone, ethyl methyl ketone, acetonitrile, dimethyl acetamide, and ether glycols. The organic solvent may be used alone or in a combination of two or more.

The dissolved state of the water-soluble resin in the mixture 26 can be regulated, for example, by regulating the concentration of the water-soluble resin, the type of the organic solvent, and the ratio of water to the total amount of the solvent. Usually, the concentration of the solid component in a mixture is low when a thin protective film is to be formed. When a thick protective film is to be formed, it is desirable to increase the concentration of the solid component in the mixture 26. By increasing the concentration of the solid component in the mixture 26, it is possible not only to easily control the film thickness that can be formed by a single application, but also to improve the productivity by that effect. The concentration of the solid component in the mixture 26 is, for example, 200 g/L or more, and may be 230 g/L or more. The concentration of the solid component in the mixture 26 is, for example, 500 g/L or less.

The concentration of the solid component in a mixture means the mass (g) per liter of the mixture of the components contained in the mixture other than the solvent (more specifically, the total weight of the components remaining after drying the mixture (or after volatilizing the solvent in the mixture). It is sufficient that the solid component is solid before being dissolved in the solvent, and is usually in a state in which it is dissolved in the solvent in the mixture.

The mixture 26 may contain a photosensitizer that absorbs the laser light irradiated in the laser grooving step. The use of the photosensitizer facilitates the control of the absorption coefficient of the protective film 28. Accordingly, even when the thickness of the protective film 28 is large, the irradiation energy can be efficiently supplied to the water-soluble resin, and it is therefore possible to increase the abrasion properties with a small amount of energy. The photosensitizer may be selected according to the wavelength of the laser light and the type of the water-soluble resin, for example. Examples of the photosensitizer include, but are not limited to, hydrocarbons (e.g., acenaphthene, perylene), compounds having an amino group and/or a nitro group (e.g., picramide, 2-nitro acenaphthene), quinones (e.g., anthraquinones such as 2-ethyl anthraquinone), xanthones, anthrones, ketones (e.g., benzophenones), and pigments (e.g., phthalocyanine). The photosensitizer may be used alone or in combination of two or more.

If necessary, the mixture 26 may further contain an additive. For example, it is preferable that the mixture 26 contains a metal corrosion inhibitor since the corrosion of the electrode by water can be suppressed. Examples of the metal corrosion inhibitor include phosphoric acid salts, amine salts, and lower aliphatic acids and salts thereof. The metal corrosion inhibitor may be used alone or in a combination of two or more.

The pH of the mixture 26 is not particularly limited, and is preferably 5 or more and 8 or less, and may be 6 or more and 8 or less, from the viewpoint of inhibiting an electrode (especially, an electrode that uses an aluminum metal) from being corroded by the mixture 26.

The viscosity of the mixture 26 can be determined according to the coating method, for example. The viscosity of the mixture 26 at 20° C. is, for example, 100 mPa·s or less, and may be 50 mPa·s or less. If the viscosity is within such a range, the thickness of the protective film 28 formed can be made uniform by the self-leveling effect.

Note that the viscosity of the mixture 26 is measured using a rotational viscometer at a shear rate of 1 s⁻¹.

In the case of drying a coating film formed by application of the mixture 26, drying can be performed under heating, and is performed at preferably a temperature lower than the heat-resistant temperature of the holding sheet, for example, 50° C. or less, more preferably less than 50° C. (e.g., 40° C. or less). Since the melting point and/or the decomposition temperature of the water-soluble resin are high as described above, the water-soluble resin, unlike PVA, can ensure high resistance of the protective film in the dicing step, without performing heating (e.g., heating at a temperature exceeding 50° C.). If heating at a temperature exceeding 50° C. is not performed, the time required for heating and cooling can be shortened or eliminated, thus also providing an advantage in increasing the productivity. From the viewpoint of increasing the productivity, drying may be performed under reduced pressure.

If the thickness of the protective film 28 is increased (e.g., 1 μm or more, preferably 2 μm or more, or 5 μm or more) in order to provide the resistance to plasma and high temperature in the dicing step, a large amount of energy will be required to remove the protective film 28 on the dividing regions R2 in the laser grooving step. When a large amount of energy is applied to the protective film 28 by the laser light in the laser grooving step, an excessive heat is also applied to the surrounding area, so that the constituent materials of the protective film 28 tend to be melted and flow into the grooves that have been formed, or to be softened to cause a reduction in the inclination of the side walls of the grooves, or to be thermally decomposed to cause a local reduction in the film thickness. As a result, the shape of the grooves is distorted, thus making it difficult to perform uniform dicing processing. In addition, the protective film 28 tends to be peeled off from the substrate 1 during plasma etching. In the case of performing dicing using a cutting blade or the like, it is not necessary to increase the thickness of the protective film 28 (usually, the thickness of the protective film is less than 1 μm), so that the above-described problem does not occur. Therefore, it can be said that the above-described problem is unique to dicing processing performed by plasma etching.

In the present disclosure, the protective film 28 that is formed by application of the mixture 26 has an absorption coefficient of 1 abs·L/g·cm⁻¹ or more for the wavelength of the laser light irradiated in the laser grooving step. If the protective film 28 exhibits such an absorption coefficient, the abrasion of the protective film 28 in a laser irradiation section can easily occur with a small amount of energy even when the protective film 28 has a large thickness. Since an excessive heat does not tend to be transferred to the surrounding area, it is possible to inhibit the constituent materials of the protective film 28 from being softened or melted to flow into the dividing regions R2, or inhibit the constituent materials of the protective film 28 from being thermally decomposed to cause a local reduction in the film thickness. Accordingly, in the laser grooving step, it is possible to form neatly shaped dividing regions R2 that are suitable for dicing. In addition, in the laser grooving step, it is possible to form processing grooves having a high aspect ratio, wherein the inclination of the side surfaces of the processing grooves is steep (forward-tapered or vertical), and the opening width thereof is narrow and substantially equal to the laser irradiation width. Further, the degradation and the deformation of the protective film 28 during plasma etching can be suppressed, and the peeling of the protective film 28 from the substrate 1 can be suppressed. Accordingly, more uniform dicing processing can be performed by plasma etching.

The absorption coefficient of the protective film 28 may be 1 abs·L/g·cm⁻¹ or more, and may be 2 abs·L/g·cm⁻¹ or more, or 4 abs·L/g·cm⁻¹ or more. The absorption coefficient can be regulated by regulating the type and/or the ratio of the constituent components of the mixture (or the protective film 28), such as a water-soluble resin and a photosensitizer.

The absorption coefficient of the protective film 28 can be determined, for example, by preparing a sample by dissolving the protective film 28 in a solvent having a small absorption for the light having a wavelength within the measurement range of a spectrometer, placing the sample in a load cell (usually, 1 cm per side), and measuring the spectrum. If the absorption falls outside the measurement range, a sample concentrated or diluted at a predetermined ratio may be prepared.

The thickness of the protective film 28 that is formed in the present step can be regulated according to, for example, the degree of irregularities on the front surface 1a of the substrate 1 or the plasma etching condition in the dicing step. In the present disclosure, dicing is performed by plasma etching, and it is therefore necessary to increase the thickness of the protective film 28 as compared with the conventional dicing using a cutting blade or the like. The thickness of the protective film 28 is, for example, 1 μm or more, preferably 2 μm or more, and may be 3 μm or more or 5 μm or more, or may be greater than 5 μm. From the viewpoint of protecting the element regions, the thickness of the protective film 28 is, for example, 5 μm or more at minimum, and 100 μm or less at maximum.

Note that the thickness of the protective film 28 can be determined according to the following procedure, based on the layer structure of the substrate, the etching properties of each of the layers, and the etching properties of the water-soluble protective film.

The layer structure of the substrate includes, for example, a device layer/a Si layer/an insulating film layer (e.g., a SiO₂ layer)/a resin layer (e.g., a die attach film layer) in this order from the upper layer side. The protective film 28 is formed so as to cover the device layer. The layer structure of the substrate is not limited to this example, and may include, for example, a Si layer/a resin layer/a Si layer. Here, the method for determining the thickness of the protective film will be described, taking, as an example, a case where the layer structure of the substrate includes a device layer/a Si layer/an insulating film layer (e.g., a SiO₂ layer)/a resin layer (e.g., a die attach film layer) in this order from the upper layer side. Note that, for the dicing of the substrate, it is necessary to cut the protective film 28, the device layer, the Si layer, the insulating film layer, and the resin layer in the dividing regions. Since the cutting of the protective film 28 and the device layer in the dividing regions is performed by laser grooving, the objects to be cut in the plasma dicing are the Si layer, the insulating film layer, and the resin layer. The thickness of the protective film 28 needs to be set such that the protective film 28 covering the element regions will not be eliminated completely while the Si layer, the insulating film layer, and the resin layer are being removed by plasma etching.

The thickness T of the water-soluble protective film can be determined by the following mathematical expression:

T=(Thickness of Si layer/A×α)+(Thickness of insulating film layer/B×β)+(Thickness of resin layer/C×γ)+D

(where A represents the ratio (selection ratio) between the etching rate of the water-soluble protective film and the etching rate of the Si layer under the conditions for performing plasma etching of the Si layer; B represents the ratio (selection ratio) between the etching rate of the water-soluble protective film and the etching rate of the insulating film layer under the conditions for performing plasma etching of the insulating film layer; C represents the ratio (selection ratio) between the etching rate of the water-soluble protective film and the etching rate of the resin layer under the conditions for performing plasma etching of the resin layer; D represents the residual thickness of the protective film that is to be left on the element regions after plasma dicing; α represents the margin value for over etching the Si layer; β represents the margin value for over etching the insulating film layer; and γ represents the margin value for over etching the resin layer.)

The residual thickness D of the protective film is determined taking into consideration, for example, the surface level difference in the element regions, the coverage of the water-soluble protective film and/or the uniformity of the water-soluble protective film. The residual thickness D is set to be, for example, preferably about 1 to 5 μm. α, β, and γ are each determined taking into consideration, for example, the thickness of the corresponding layer and/or the etching uniformity. α, β, and γ are each set to be, for example, about 1.1 to 1.2.

The selection ratio between each of the layers and the water-soluble protective film is determined according to, for example, the element structure and/or the plasma etching conditions of each of the layers. The selection ratio A is 50 to 100, for example. The selection ratio B is 1 to 5, for example. The selection ratio C is 0.5 to 2, for example.

In terms of productivity and/or cost, the thickness of the water-soluble protective film is preferably set within such a range that the residual film is left, in view of the selection ratio obtained from the above-described expression and the actual processing conditions.

### (c) Laser Grooving Step

FIG. 5 is a schematic cross-sectional view for illustrating a laser grooving step. In the laser grooving step, the portions of the protective film 28 that cover the dividing regions R2 are irradiated with laser light, to remove the protective film 28 in these portions, and expose the front surface 1a of the substrate 1 in the dividing regions R2. When the multilayer wiring layer 30 and the insulating protective layer 31 that protects the multilayer wiring layer 30 are disposed under the protective film 28 that covers the dividing regions R2 of the substrate, the multilayer wiring layer 30 and the insulating protective layer 31 are also removed by irradiation with laser light, to expose the front surface 1a of the substrate 1 in the dividing regions R2. Consequently, a predetermined pattern is formed by the remaining protective film 28. According to the present disclosure, the protective film 28 is formed using a mixture containing a water-soluble resin having a melting point of 250° C. or more, or a decomposition temperature of 450° C. or more, and the protective film 28 has an absorption coefficient of 1 abs·L/g·cm⁻¹ or more for the wavelength of the laser light irradiated in the laser grooving step. Accordingly, during laser grooving, it is possible to inhibit an excessive heat from being applied to the surrounding area even when the protective film 28 has a large thickness, making it possible to form neatly shaped grooves.

The processing by laser grooving can be performed in the following manner. As the laser light source, it is possible to use, for example, a UV-wavelength nanosecond laser. Then, the portions of the protective film 28 that cover the dividing regions R2 are irradiated with the laser light, to remove the protective film 28 in these portions. The irradiation conditions are not particularly limited, and the laser light may be irradiated, for example, with a pulse cycle of 200 kHz, an output of 0.3 W, and a scan rate of 400 mm/sec. When the multilayer wiring layer 30 is disposed under the protective film 28 on the dividing regions R2, the processing by laser grooving may be performed in the following manner. First, irradiation of the dividing regions R2 with the laser light is performed twice with a pulse cycle of 200 kHz, an output of 0.3 W, and a scan rate of 400 mm/sec, to remove the protective film 28. Thereafter, irradiation of the dividing regions R2 with the laser light is performed once with a pulse cycle of 100 kHz, an output of 1.7 W, and a scan rate of 400 mm/sec, to remove the multilayer wiring layer 30. Although the processing conditions of the nanosecond laser are described here as an example, the laser is not limited to the nanosecond laser. As the laser, it is possible to use, for example, sub-picosecond to sub-nanosecond lasers. For the pulse width of this range, a processing phenomenon called thermal processing is predominant, and it is therefore possible to use the method according to the present disclosure.

The wavelength of the laser light that is irradiated is 200 nm or more 430 nm or less, for example. From the viewpoint of increasing the precision of the groove formation during the laser grooving, the wavelength is preferably 250 nm or more and 360 nm or less. With the use of the laser light with such a wavelength, it is possible to easily form a groove having a small width.

During laser grooving, the temperatures of the substrate 1 and the holding sheet 3 are preferably maintained at 50° C. or less.

### (d) Dicing Step (Plasma Etching Step)

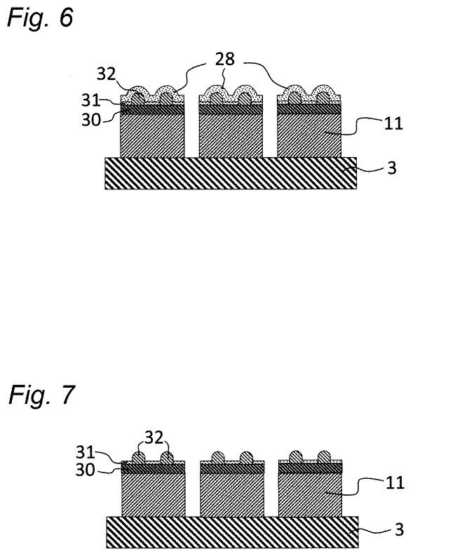

FIG. 6 is a schematic cross-sectional view for illustrating element chips that have been diced by a dicing step. In the dicing step, in the dividing regions R2 of the substrate 1 shown in FIG. 5, which have been exposed in the laser grooving step, plasma etching is performed from the front surface 1a to the back surface 1b of the substrate 1 to attain the state shown in FIG. 6, to dice the substrate 1 into element chips 11 corresponding to a plurality of element regions R1. In the present step, plasma etching is performed using a patterned protective film 28 as a mask.

In the following, the plasma etching step and an example of a dry etching apparatus (or plasma treatment apparatus) used therein will be described.

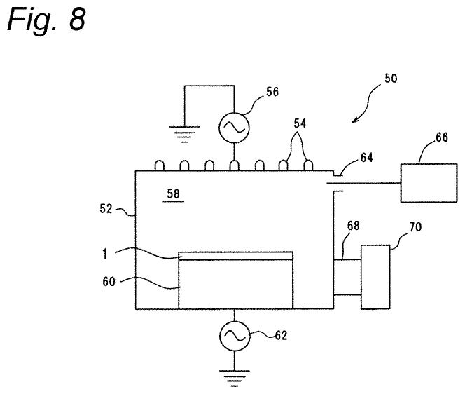

FIG. 8 is a schematic diagram showing an example of a dry etching apparatus 50 used in the present step. A dielectric window (not shown) is provided at the top of a chamber 52 of the dry etching apparatus 50, and antennas 54 serving as upper electrodes are disposed above the dielectric window. The antennas 54 are electrically connected to a first high-frequency power supply section 56. On the other hand, a stage 60 on which the substrate 1 fixed to the transport carrier 4 is to be disposed is disposed on the bottom side of a processing room 58 in the chamber 52. A refrigerant flow channel (not shown) is formed inside the stage 60, and the stage 60 is cooled by circulating a refrigerant through the refrigerant flow channel. The stage 60 also functions as a lower electrode, and is electrically connected to a second high-frequency power supply section 62. In addition, the stage 60 includes an electrostatic chucking electrode (ESC electrode), which is not shown, and the substrate 1 that is fixed to the transport carrier 4 placed on the stage 60 can be electrostatically chucked to the stage 60. In addition, the stage 60 is provided with a cooling gas hole (not shown) for supplying a cooling gas, and the substrate 1 that is fixed to the transport carrier 4 electrostatically chucked to the cooled stage 60 can be cooled by supplying a cooling gas such as helium from the cooling gas hole. A gas introduction port 64 of the chamber 52 is fluidly connected to an etching gas source 66, and an exhaust port 68 is connected to a vacuum evacuation section 70 including a vacuum pump for vacuum evacuating the chamber 52.

After the transport carrier 4 and the substrate 1 shown in FIG. 3 have been placed on the stage 60 in the chamber 52, the pressure inside the chamber 52 is reduced using the vacuum pump, and a predetermined process gas is introduced into the chamber 52. Then, the dividing regions R2 of the substrate 1 in the chamber 52 are dry-etched by a plasma of the process gas that has been formed by supplying high-frequency power to the antennas 54 (plasma source), and the substrate 1 is divided into a plurality of element chips 11 including the element regions R1, as shown in FIG. 6.

The dry etching apparatus also includes a control device that controls the process gas source, an ashing gas source, the vacuum pump, and the high-frequency power supply sections 56 and 62, and controls the above-described constituent elements so as to perform plasma etching under the optimized dry etching conditions.

If the substrate 1 is made of silicon, etching can be performed by the BOSCH method in the plasma etching step. In the BOSCH method, a plasma for depositing a passivation film and a plasma for etching silicon are alternately generated. The plasma for depositing a passivation film may be generated for about 2 to 10 seconds, for example, by adjusting the chamber pressure to 20 Pa while supplying C₄F₈ at 300 sccm, and applying RF power of 2000 to 5000 W to the antennas 54. The plasma for etching silicon may be generated for about 5 to 20 seconds, for example, by adjusting the chamber pressure to 20 Pa while supplying SF₆ at 600 sccm, and applying RF power of 2000 to 5000 W to the antennas 54 and applying LF power of 50 to 500 W to the lower electrode. Note that, in order to suppress notching in the processed shape of the substrate 1 (the semiconductor layer), the RF power applied to the lower electrode may be applied in a pulsed manner. By repeating the generation of the plasma for depositing a passivation film and the plasma for etching silicon, for example, for about 20 cycles, the substrate 1 having a thickness of 100 μm can be etched and divided into the element chips 11. Note that, in order to reduce the thermal damage caused by the plasma generated in the plasma etching step, it is preferable that the transport carrier 4 and the substrate 1 are cooled in the plasma etching step. For example, the transport carrier 4 and the substrate 1 can be cooled by applying a DC voltage of 3 kV to the ESC electrode while regulating the temperature of the stage 60 to 20° C. or less, and supplying 50 to 200 Pa of He as a cooling gas between the holding sheet 3 and the stage 60. If the substrate 1 has a thickness less than or equal to a predetermined thickness (e.g., 30 μm or less), silicon may be continuously etched without using the BOSCH method.

Molten debris of the metals, the insulators, and Si contained in the multilayer wiring layer 30, the insulating protective layer 31, and the protective film 28 may be attached to the dividing regions R2 exposed by laser grooving. When the above-described etching of silicon by the BOSCH method or the like is performed in a state in which the debris are attached, the debris may cause a columnar residue and etching stop, or may roughen the mask surface. Therefore, before performing the etching of silicon by the BOSCH method or the like, it is preferable to perform plasma etching under strongly ionic conditions, thus removing the debris attached to the dividing regions R2. This can prevent the generation of a columnar residue or etching stop during the etching of silicon by the BOSCH method or the like, achieve a good processed shape and improve the processing stability. As the plasma used for removing debris, it is preferable to use a gaseous species capable of removing silicon and a silicon oxide layer. For example, the plasma may be generated by adjusting the chamber pressure to 5 Pa while supplying a mixed gas of SF₆ and O₂ at 200 sccm, and applying RF power of 1000 to 2000 W to the antennas 54, and debris may be exposed to the plasma for about 1 to 2 minutes. At this time, the debris removing effect can be increased by applying LF power of about 150 W to the lower electrode included in the stage 60.

### (e) Protective Film Removal Step

FIG. 7 is a schematic cross-sectional view for illustrating the element chips in a state in which the protective film has been removed. In the protective film removal step, the portions of the protective film 28 that cover the element regions R1 are removed on the element chips 11, which have been diced in the dicing step, as shown in FIG. 6. Since the protective film 28 contains a water-soluble resin, the protective film 28 on the element chips 11 can be easily removed by being brought into contact with an aqueous liquid cleaner.

As the aqueous liquid cleaner, it is possible to use water, or use a solvent mixture of water and an organic solvent. As the organic solvent, it is possible to use, for example, any of the organic solvents shown as the examples of the solvent for forming the protective film 28. If necessary, the aqueous liquid cleaner may contain an additive. Examples of the additive include an acid, a surfactant, and a metal corrosion inhibitor.

It is sufficient that the aqueous liquid cleaner is brought into contact with the protective film 28, and it is possible to efficiently remove the protective film 28 by spraying the aqueous liquid cleaner thereto by two-fluid spraying or the like. More efficient cleaning can be performed by removing most of the protective film by rinsing, thereafter performing cleaning by two-fluid spraying, and finally performing washing off.

In the removal step, before bringing the protective film 28 into contact with the aqueous liquid cleaner, the surface of the protective film 28 may be subjected to a plasma containing oxygen (be subjected to ashing treatment), to partially remove the protective film 28. When performing plasma etching, a layer resulting from modification or curing of the constituent materials of the protective film 28 may be formed on the surface of the protective film 28. However, such a layer can be removed by ashing treatment, so that it is possible to easily remove the protective film 28 by using the aqueous liquid cleaner.

The ashing treatment may be subsequently performed in the chamber 52 in which the plasma etching in the dicing step has been performed. In the ashing treatment, the protective film 28 can be removed from the front surface 1a of the substrate 1 in the chamber 52 by using a plasma of an ashing gas formed by introducing the ashing gas (e.g., oxygen gas) into the chamber 52, and similarly supplying high-frequency power to the antennas 54 (plasma source).

In the ashing treatment, the processing room 58 shown in FIG. 8 is vacuum evacuated by the vacuum evacuation section 70, and an etching gas containing, for example, oxygen is supplied from the etching gas source 66 into the processing room 58. Then, the pressure inside the processing room 58 is maintained at a predetermined pressure, and high-frequency power is supplied from the first high-frequency power supply section 56 to the antennas 54, to generate a plasma in the processing room 58, and the substrate 1 is irradiated with the plasma, i.e., the surface of the protective film 28 is subjected to the plasma. At this time, by physicochemical action between radicals and ions in the plasma, the protective film 28 is partially removed (light ashing). Accordingly, it is possible to easily remove the protective film 28 by using the above-described aqueous liquid cleaner.

### EXAMPLES

Hereinafter, the present disclosure will be specifically described by way of examples and comparative examples. However, the present disclosure is not limited to the following examples.

### Example 1

### (1) Preparation of Substrate

A transport carrier 4 holding a silicon substrate 1 was prepared. A plurality of element regions R1 were formed on the silicon substrate 1, and each of the element region R1 was surrounded by a dividing region R2.

### (2) Protective Film Formation

Polystyrene sulfonic acid sodium salt was dissolved in a solvent mixture of water and acetone (water:acetone=1:1 (mass ratio)) to prepare a coating solution (mixture). The polystyrene sulfonic acid sodium salt used here was a water-soluble resin, and had a melting point of 450° C., a decomposition temperature of about 600° C., and a laser absorption coefficient of 1.02 abs·L/g·cm⁻¹. The solid content concentration in the mixture was 200 g/L. The mixture had a viscosity of 10 mPa·s at 20° C., and a pH of 7.

The mixture was spray-coated onto the entire exposed surface of the silicon substrate 1 prepared in (1) above, to form a coating film 28. The coating film 28 was dried at room temperature under atmospheric pressure. The spray coating and the drying were repeated a plurality of times, to form a protective film 28 having a thickness of 30 μm.

### (3) Laser Grooving

Using a nanosecond laser with a wavelength of 355 nm, the protective film 28 on the dividing regions R2 of the silicon substrate 1 was irradiated with laser light, to remove the protective film 28 in these portions. The irradiation with laser light was performed for three passes with a pulse cycle of 200 kHz, an output of 0.3 W, and a scan rate of 400 mm/sec.

### (4) Dicing by Plasma Etching

The transport carrier 4 holding the silicon substrate 1 was transported into a chamber 52 included in a plasma treatment apparatus 50, and was placed on a stage 60 provided inside the chamber 52. The transport carrier 4 was placed on the stage 60 in a state in which the surface thereof holding the silicon substrate 1 faced toward upper electrodes provided at the top of the chamber 52. A plasma for depositing a passivation film and a plasma for etching silicon were alternately generated inside the chamber 52, and the silicon substrate 1 was etched in the regions where the protective film 28 had been removed. More specifically, a cycle including a step A of generating the plasma for depositing a passivation film inside the chamber 52 for 5 seconds and a step B of generating the plasma inside the chamber 52 for etching silicon for 15 seconds were repeated 20 times. The steps were performed under the following conditions.

Step A: The chamber pressure was adjusted to 20 Pa by evacuating the chamber 52 using a gas outlet valve provided inside the chamber 52, while supplying C₄F₈ at 300 sccm into the chamber 52, and RF power of 2000 W was applied to the antenna 54.

Step B: The pressure inside the chamber 52 was adjusted to 20 Pa by evacuating the chamber 52 using a gas outlet valve provided inside the chamber 52 while introducing SF₆ at a flow rate of 300 sccm into the chamber 52, and high-frequency power (RF power) of 2000 W was applied to the antenna 54, and a LF voltage of 300 W was applied to the lower electrodes.

By this etching, the portions of the silicon substrate 1 that were located in the dividing regions R2 were removed from the front surface 1a to the back surface 1b, and the silicon substrate 1 was diced into a plurality of chips 11.

### (5) Protective Film Removal

An aqueous liquid cleaner was sprayed by two-fluid spraying onto the protective film 28 remaining on the element regions R1 of the silicon substrate 1, to remove the protective film 28. Deionized water was used as the aqueous liquid cleaner.

### Comparative Example 1

In (2) Protective film formation of Example 1, a coating solution was prepared by mixing 20 g of polyvinyl alcohol, 0.2 g of ferulic acid, and 80 g of water. A protective film having a thickness of 5 μm was formed on the silicon substrate 1 in the same manner as in Example 1 except that the obtained coating solution was used. However, the time required to form the protective film having a thickness of 5 μm was 4 times or more that of Example 1. After forming the protective film, the protective film was heated at 60° C. for 10 minutes in order to provide resistance to plasma etching to the protective film. Using the substrate 1 including the heated protective film, (3) Laser grooving and (4) Dicing by plasma etching were performed in the same manner as in Example 1.

The protective film could not be removed by the same treatment as that in Example 1. Accordingly, the surface layer portion of the protective film was removed by ashing, and, thereafter, the protective film was cleaned with the aqueous liquid cleaner. More specifically, after performing dicing, the pressure inside the chamber 52 was maintained at a predetermined pressure by regulating a gas outlet valve while introducing oxygen gas into the chamber 52. Then, high-frequency power was supplied to the upper electrodes to generate an oxygen plasma inside the chamber 52, and the protective film was irradiated with the oxygen plasma. The surface layer portion of the protective film was removed by irradiation with the oxygen plasma. Then, as in the case of Example 1, the remaining portion of the protective film was removed using the aqueous liquid cleaner.

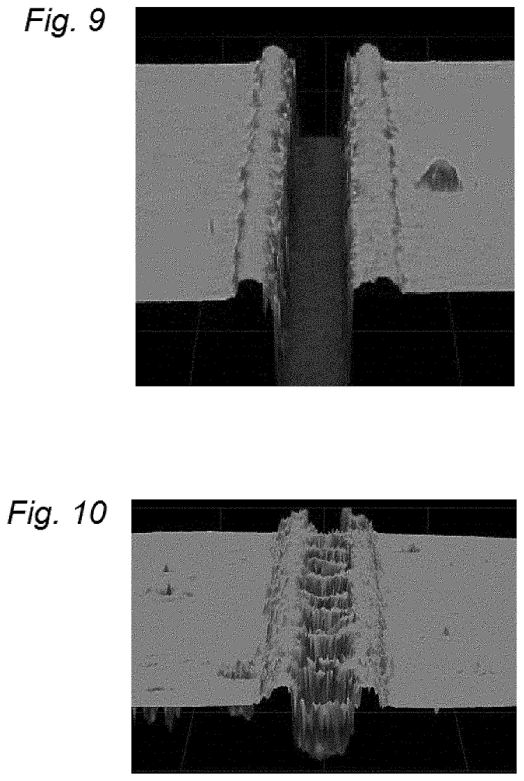

FIGS. 9 and 10 respectively show measurement results of 3D mapping using a laser microscope, showing the states of the protective films after laser grooving in Example 1 and Comparative Example 1. In Example 1, a neatly shaped groove was formed on the dividing regions R2. In contrast, in Comparative Example 1, a groove was discontinuously formed on the dividing region R2, and the protective film remained in a bridge shape between adjacent grooves.

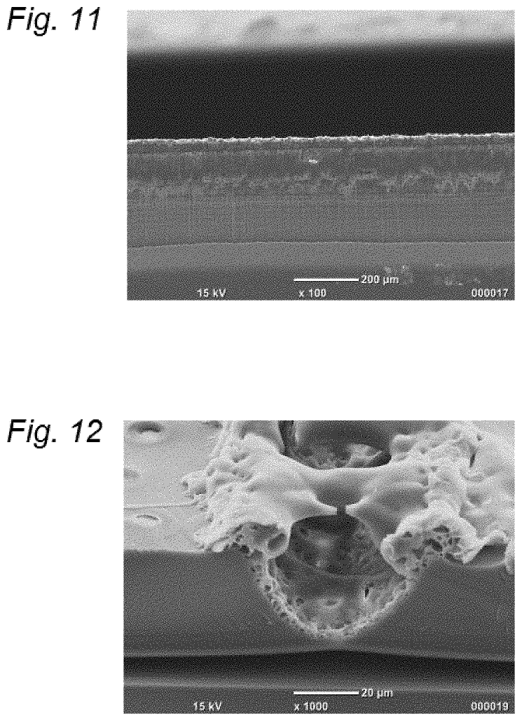

FIG. 11 and FIG. 12 respectively show SEM photographs showing the states of the protective films after dicing in Example 1 and Comparative Example 1. As shown in these drawings, no peeling of the protective film 28 was observed in Example 1. In contrast, the protective film was significantly peeled off in Comparative Example 1.

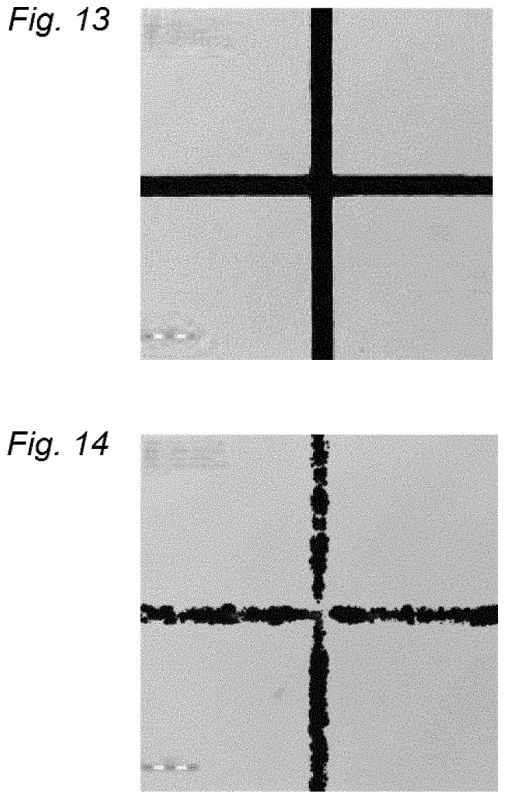

FIGS. 13 and 14 respectively show photographs, observed with a laser microscope, of the states of the element chips after removing the protective film in Example 1 and Comparative Example 1, as viewed from above. Neatly shaped, clean dividing regions R2 were formed in Example 1. In contrast, in Comparative Example 1, the shapes of the element regions R1 were distorted, and some portions remained unetched.

The method according to the present disclosure is suitable for use in forming an element chip by plasma etching.

The present invention has been described by way of preferred embodiments at present, but the disclosure should not be construed as liming the scope of the present invention. Various variations and modifications will become clearly apparent to those skilled in the art to which the present invention pertains upon reading the disclosure given above. Accordingly, the scope of the appended claims should be construed to encompass all variations and modifications without departing from the true spirit and scope of the present invention.
[Reference Numerals] 1: Substrate, 1a: First surface (front surface), 1b: Second surface (back surface), R1: Element region, R2: Dividing region, 2: Frame, 2a: Opening, 2b: Notch, 2c: Corner cut, 3: Holding sheet, 3a: Adhesive surface, 3b: Non-adhesive surface, 4: Transport carrier, 11: Element chip, 20: Nozzle, 26: Mixture, 28a: Coating film, 28: Protective film, 30: Multilayer wiring layer, 31: Protective layer, 32: Bump, 50: Dry etching apparatus, 52: Chamber, 54: Antenna, 56: First high-frequency power supply section, 58: Processing room, 60: Stage, 62: Second high-frequency power supply section, 64: Gas introduction port, 66: Etching gas source, 68: Exhaust port, 70: Vacuum evacuation section

What is claimed is:

1. A method for manufacturing an element chip, comprising:
a preparation step of preparing a substrate, the substrate having a first surface and a second surface opposite to the first surface, and including a plurality of element regions and dividing regions defining the element regions, the substrate being held on a holding sheet on the second surface side;
a protective film formation step of applying a mixture containing a water-soluble resin and a solvent to the first surface of the substrate, to form a protective film containing the water-soluble resin;
a laser grooving step of irradiating, with laser light, portions of the protective film that cover the dividing regions, to remove the portions covering the dividing regions, and expose the first surface of the substrate in the dividing regions;
a dicing step of dicing the substrate into a plurality of element chips by plasma etching the substrate from the first surface to the second surface in the dividing regions in a state in which the element regions are covered by the protective film; and
a removal step of removing the portions of the protective film that cover the element regions,
wherein the water-soluble resin has a melting point of 250° C. or more, or a decomposition temperature of 450° C. or more, and
the protective film has an absorption coefficient of 1 abs·L/g·cm⁻¹ or more for a wavelength of the laser light.

2. The method for manufacturing an element chip according to claim 1,
wherein the water-soluble resin absorbs the laser light in the laser grooving step.

3. The method for manufacturing an element chip according to claim 1,
wherein the mixture further contains a photosensitizer that absorbs the laser light.

4. The method for manufacturing an element chip according to claim 1,
wherein the substrate includes an electrode on the first surface, and
the mixture has a pH of 5 or more and 8 or less.

5. The method for manufacturing an element chip according to claim 1,
wherein the wavelength of the laser light is 250 nm or more and 360 nm or less.

6. The method for manufacturing an element chip according to claim 1,
wherein, in the removal step, the protective film is removed by being brought into contact with an aqueous liquid cleaner.

7. The method for manufacturing an element chip according to claim 1,
wherein the mixture has a viscosity of 100 mPa·s or less at 20° C.
